(19) United States
(12) Patent Application Publication
(10) Pub. No.: US 2009/0065829 A1
(43) Pub. Date: Mar. 12, 2009

(54) Image Sensor and Method for Manufacturing the Same

(76) Inventor: SEOUNG HYUN KIM, Pocheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/204,944

(22) Filed: Sep. 5, 2008

(30) Foreign Application Priority Data
Sep. 10, 2007 (KR) 10-2007-0091339

(51) Int. Cl. H01L 27/146; H01L 31/18

(52) U.S. Cl. 257/292; 438/59; 257/E27.133

(57) ABSTRACT

Provided are image sensors and a method of manufacturing the same. The image sensor can include a semiconductor substrate having a metal line and a readout circuitry formed thereon; a photodiode on the semiconductor substrate, the photodiode including a first impurity region and a second impurity region horizontally arranged in a crystalline region; and a first contact and a second contact penetrating the photodiode. The first contact can penetrate the first impurity region of the photodiode, and the second contact can penetrate the second impurity region to connect with the metal line.

### CROSS-REFERENCE TO RELATED APPLICATION

The present application claims the benefit under 35 U.S.C. §119 of Korean Patent Application No. 10-2007-0091339, filed Sep. 10, 2007, which is hereby incorporated by reference in its entirety.

### BACKGROUND

In general, an image sensor is a semiconductor device that converts an optical image to an electric signal. Image sensors are generally classified as a charge coupled device (CCD) image sensor or a complementary metal oxide silicon (CMOS) image sensor (CIS).

In a related art CIS, a photodiode is formed in a substrate with transistor circuitry using ion implantation. As the size of a photodiode reduces more and more for the purpose of increasing the number of pixels without an increase in a chip size, the area of a light receiving portion reduces, so that an image quality reduces.

Also, since a stack height does not reduce as much as the reduction in the area of the light receiving portion, the number of photons incident to the light receiving portion also reduces due to diffraction of light, called airy disk.

As an alternative to overcome this limitation, an attempt of forming a photodiode using amorphous silicon (Si), or forming a readout circuitry in a Si substrate and forming a photodiode on the readout circuitry using a method such as wafer-to-wafer bonding has been made (referred to as a “three-dimensional (3D) image sensor). The photodiode is connected with the readout circuitry through a metal line.

Meanwhile, according to a related art, since both the source and drain of a transfer transistor are heavily doped with N-type impurities, a charge sharing phenomenon occurs. When the charge sharing phenomenon occurs, the sensitivity of an output image is reduced and an image error may be generated.

Also, according to the related art, since a photo charge does not smoothly move between the photodiode and the readout circuitry, a dark current may be generated or saturation and sensitivity are reduced.

### BRIEF SUMMARY

Embodiments of the present invention can provide an image sensor and method for manufacturing the same.

In an embodiment, a method for manufacturing an image sensor can include: preparing a first substrate on which metal lines and a readout circuitry are formed; providing a photodiode including a first impurity region and a second impurity region in a crystalline region on the first substrate; and forming a plurality of first contacts and a plurality of second contacts penetrating the photodiode to be connected with corresponding ones of the metal lines and spaced apart from each other, the plurality of first contacts being in contact with the first impurity region and the plurality of second contacts being in contact with the second impurity region. The first impurity region and the second impurity region can be laterally formed in the crystalline region.

In another embodiment, an image sensor can include: a semiconductor substrate having a metal line and a readout circuitry formed thereon; a photodiode on the semiconductor substrate, the photodiode including a first impurity region and a second impurity region in a crystalline region; and a first contact and a second contact penetrating the photodiode, wherein the first contact penetrates the first impurity region and the second contact penetrates the second impurity region to connect to the metal line. The metal line can electrically connect the photodiode to the readout circuitry. In one embodiment the second first contact can connect the second impurity region to peripheral circuitry or an electrode for applying a reset operation.

The details of one or more embodiments are set forth in the accompanying drawings and the description below. Other features will be apparent from the description and drawings, and from the claims.

### BRIEF DESCRIPTION OF THE DRAWINGS

FIGS. 1 to 7 are cross-sectional views illustrating a method for manufacturing an image sensor according to an embodiment.

### DETAILED DESCRIPTION

Embodiments of an image sensor and a manufacturing method thereof will be described in detail with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

The present embodiments are not limited to a CMOS image sensor and may be applied to other image sensors incorporating a photodiode.

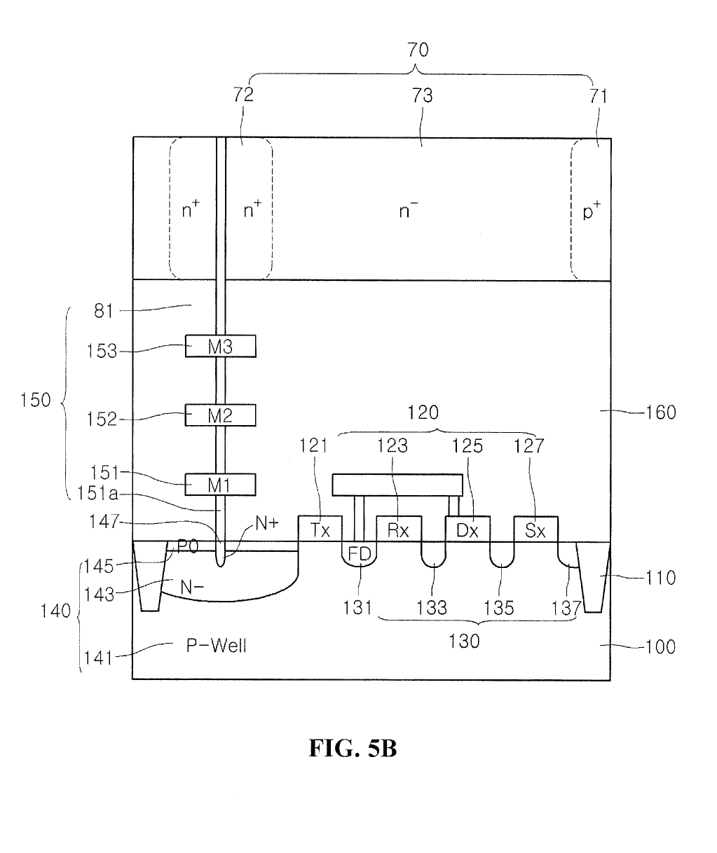

Referring to FIG. 5A, an image sensor according to an embodiment includes a circuitry layer 20, a metal line layer 30, a photodiode 70 and first and second contacts 81 and 82 on a first substrate 100.

FIG. 5B provides a detailed view of the first substrate 100 on which the circuitry layer 20, and a metal line 150 of the metal line layer 30 are formed, and illustrates a portion of a unit pixel according to one embodiment.

The circuitry layer 20 can have a circuitry including a readout circuitry 120, and the metal line layer 30 can include the metal line 150 connected with the circuitry.

As shown in FIGS. 5A-5B, the photodiode 70 can be formed in a crystalline substrate and can include a first impurity region 71, a second impurity region 72, and a third impurity region 73.

The first impurity region 71 can be formed by using p-type impurities, the second impurity region 72 can be formed by using n-type impurities at a high concentration, and the third impurity region 73 can be formed by using n-type impurities at a low concentration.

At this time, the second impurity region 72 can be formed for an ohmic contact. However, in certain embodiments one of the n-type impurity regions can be omitted.

For example, while the present embodiment shows and describes the photodiode 70 as including the first, second and third impurity regions 71, 72 and 73, it is not limited thereto. For example, the photodiode 70 can be formed by only the first and second impurity regions 71 and 72.

The first contact 81 penetrates the first impurity region 71 and the second contact 82 penetrates the second impurity region 72.

At this time, the photodiode 70 can be positioned between the first contact 81 and the second contact 82, and may be formed symmetrically with another adjacent photodiode. For example, adjacent photodiodes can be symmetrical about the longitudinal axis of each contact.

The second contact 82 contacting the first impurity region 71 can be used to remove holes in the first impurity region 71, and the first contact 81 contacting the second impurity region 72 can transmit a signal generated in the photodiode 70 to a circuitry region. The second contact 82 can be connected to a power/ground line or circuitry through the metal line layer 30. In one embodiment, the second contact 82 can be connected to apply a potential or ground during a reset operation such that holes can be removed from the first impurity region 71.

Although not shown in the drawings, a color filter array and a microlens can be further formed on the photodiode 70.

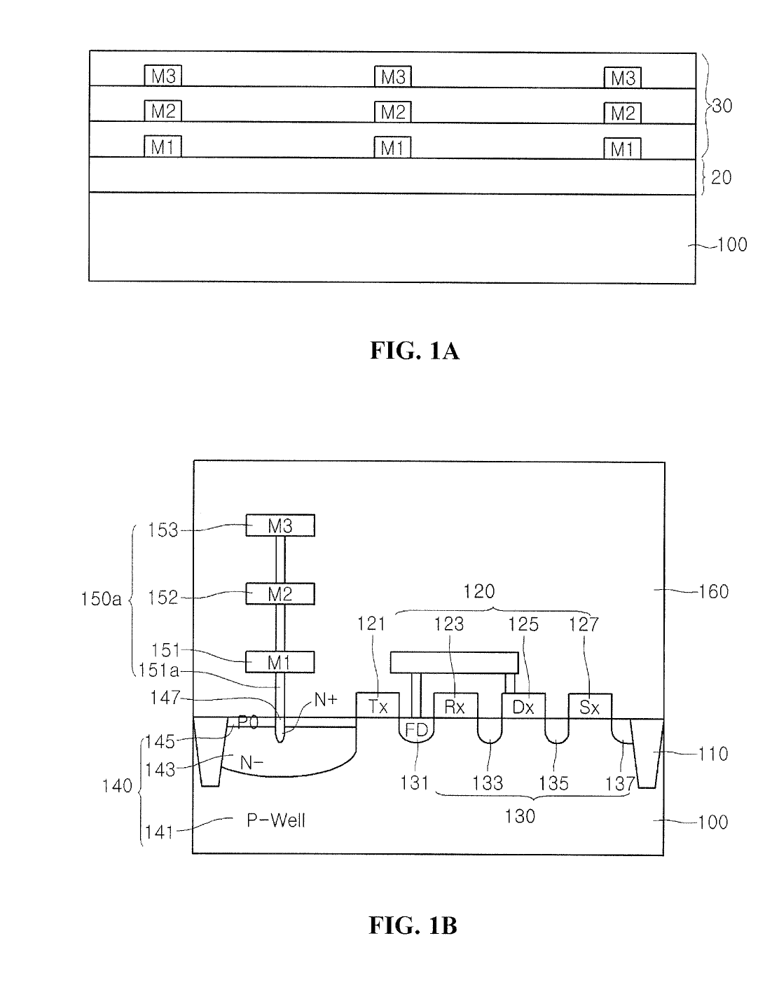

FIGS. 1 through 5 are cross-sectional views illustrating a method for manufacturing an image sensor according to an embodiment.

As shown in FIGS. 1A and 1B, a first substrate 100 including a circuitry layer 20 and a metal line layer 30 can be prepared.

FIG. 1A is a cross-sectional view of the first substrate 100 including the circuitry layer 20 and the metal line layer 30, and FIG. 1B is a detailed view according to one embodiment of the first substrate 100 on which the circuitry layer 20, and a metal line 150a of the metal line layer 30 are formed.

The circuitry layer 20 can include a readout circuitry 120, and the metal line layer 30 can include the metal line 150a connected with the circuitry.

Referring to FIG. 1B, the first substrate 100 on which the metal line 150a and the readout circuitry 120 are formed can be prepared. The first substrate can include a p-type region or a p-well 141. In an embodiment, a device isolation layer 110 can be formed in the first substrate 100 to define an active region, and the readout circuitry 120 including a transistor can be formed on the active region. For example, the readout circuitry 120 can include a transfer transistor (Tx) 121, a reset transistor (Rx) 123, a drive transistor (Dx) 125, and a select transistor (Sx) 127. After forming gates for the transistors, an ion implantation region 130 including a floating diffusion region (FD) 131 and source and drain regions 133, 135, 137 for the respective transistors can be formed. Also, according to an embodiment, a noise filtering circuitry (not shown) may be further provided to enhance the sensitivity.

The forming of the readout circuitry 120 in the first substrate 100 can include forming an electrical junction region 140 in the first substrate 100, and a first conductive type connection region 147 connected with the metal line 150a on the electrical junction region 140.

The electrical junction region 140 can be a PN junction 140, but embodiments are not limited thereto. In an embodiment, the electrical junction region 140 can include a first conductive type ion implantation layer 143 on a second conductive type well 141 (or a second conductive type epitaxial layer), and a second conductive type ion implantation layer 145 on the First conductive type ion implantation layer 143. For example, the PN junction 140 can be a P0(145)/N−(143)/P−(141) junction as shown in FIG. 1B, but embodiments are not limited thereto. In an embodiment, the first substrate 100 can be a second conductive type substrate, but embodiments are not limited thereto.

According to the present embodiment, it can be possible to fully dump photo charge from the photodiode by allowing a potential difference to be generated between the source and drain of the transfer transistor Tx. Thus, as the photo charge generated in the photodiode is dumped into the floating diffusion region, the sensitivity of an output image can be enhanced.

That is, by forming the electrical junction region 140 in the first substrate 100 on which the readout circuitry 120 is formed, a potential difference can be generated between the source and drain of the transfer transistor (Tx) 121 to fully dump the photo charge.

Hereinafter, a structure for dumping the photo charge according to an embodiment will be described in more detail.

In this embodiment, unlike a floating diffusion (FD) node 131 that is an N+ junction, a PNP junction 140, which is the electrical junction region, is pinched off at a constant voltage before an application voltage is completely transferred. This constant voltage is called a ‘Pinning Voltage’, which depends on the doping concentrations of the P0 region 145 and the N-region 143.

Specifically, electrons generated in the photodiode 70 (see FIG. 5B) move to the PNP junction 140, and when the transfer transistor (Tx) 121 is turned on, the electrons are transferred to the FD node 131 and then converted to a voltage.

Since a maximum voltage of the P0/N−/P− junction 140 becomes the pinning voltage and a maximum voltage of the FD node 131 becomes the threshold voltage Vdd-Rx 123, the electrons generated in the photodiode 70 can be completely dumped without charge sharing due to the potential difference between the sides of the transfer transistor (Tx) 131.

That is, according to an embodiment, the P0/N-/P-well junction is formed in the first substrate 100 to allow a positive (+) voltage to be applied to the N-region 143 of the P0/N−/P−well junction and a ground voltage to be applied to the P0 region 145 and the P−well 141 during a 4-Tr active pixel sensor (APS) reset operation, so that the P0/N−/P−well double junction is pinched off like in a BJT structure at a voltage above a predetermined voltage. This voltage is called ‘Pinning Voltage’. Accordingly, a potential difference is generated between the source and drain at sides of the transfer transistor (Tx) 121. In addition, during the On/Off operations of the transfer transistor (Tx), the charge sharing phenomenon can be inhibited.

Unlike in the related art where the photodiode is simply connected to an N+ junction, embodiments of the present invention can inhibit reduction of the saturation and sensitivity.

Also, according to an embodiment, a first conductive type connection region 147 can be formed between the photodiode and the readout circuitry to provide a smooth passage of the photo charge, thereby minimizing a dark current source and further inhibiting the saturation and sensitivity from being reduced.

For this purpose, the first conductive type connection region 147 for an ohmic contact can be formed on a portion of the surface of the P0/N−/P− junction 140. The N+ region 147 can be formed to penetrate the P0 region 145 and contact the N-region 143.

Meanwhile, to inhibit the first conductive type connection region 147 from becoming a leakage source, the width of the first conductive type connection region 147 can be minimized. For this purpose, in one embodiment a plug implant can be performed after etching a via hole for a first metal contact 151a. In another embodiment, an ion implantation pattern can be formed on the first substrate, and the first conductive type connection region 147 can be formed using the ion implantation pattern as an ion implantation mask.

That is, a reason that N+ impurities are locally doped in only a portion where the contact is formed is to minimize a dark signal and facilitate ohmic contact formation. If the entire region of the source of the transfer transistor Tx is N+ doped, a dark signal may increase due to dangling bonds on the Si substrate.

An interlayer insulating layer 160 can be formed on the first substrate 100 and a metal line 150a can be formed in the interlayer insulating layer 160. The metal line 150a can include the first metal contact 151a, a first metal 151, a second metal 152, and a third metal 153, but embodiments are not limited thereto.

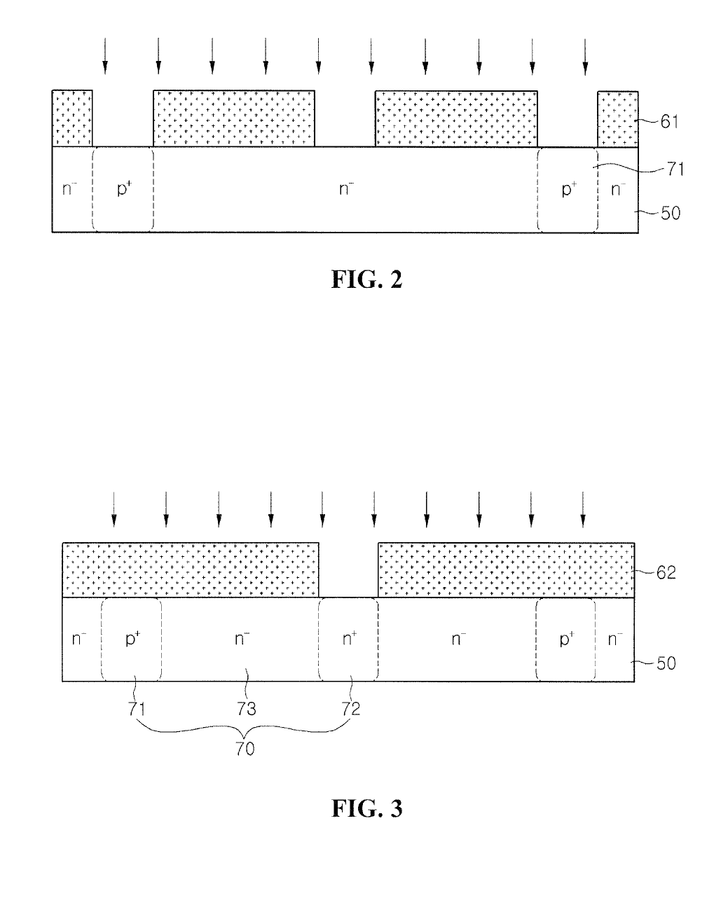

Referring to FIG. 2, a first impurity region 71 can be formed in a second substrate 50.

In one embodiment, the second substrate 50 can be formed of n-type crystalline silicon lightly doped with n-type impurities. In a further embodiment, an oxide layer can be provided on the second substrate 50.

According to an embodiment, the first impurity region 71 can be formed by forming a first photoresist pattern 61 on the second substrate 50 and implanting p-type impurities into the first substrate 50 through a first ion implantation process.

Thereafter, referring to FIG. 3, the first photoresist pattern 61 can be removed, a second photoresist pattern 62 can then be formed on the second substrate 50, and a second ion implantation process can be performed to form a second impurity region 72 in the second substrate 50.

The second impurity region 72 can be formed by implanting n-type impurities at a high concentration.

At this time, for embodiments where the second substrate is a n-type crystalline silicon, the third impurity region 73 lightly doped with n-type impurities is provided between the first impurity region 71 and the second impurity region 72 by the lightly doped n-type substrate, so that a photodiode 70 is formed.

The second impurity region 72 can be formed for an ohmic contact. In certain embodiments, the second impurity region 72 can be omitted, and the third impurity region 73 can be used as the second impurity region.

To activate the first, second and third impurity regions 71, 72 and 73, a thermal annealing can be performed.

While the present embodiment describes that the second substrate 50 is formed of n-type crystalline silicon, it is not limited thereto. For example, the second substrate 50 can be formed of p-type crystalline silicon.

When the second substrate 50 is the n-type substrate, the first impurity region 71 and the second impurity region 72 can be formed by an ion implantation process. However, if the second substrate 50 is a p-type substrate, the photodiode 70 can be formed by implanting n-type impurities at a low concentration to form the third impurity region 73 and implanting n-type impurities at a high concentration to form the second impurity region 72.

Also, while the present description shows and describes that the photodiode 70 includes the first impurity region 71 doped with p-type impurities, the third impurity region 73 lightly doped with n-type impurities, and the second impurity region 72 heavily doped with n-type impurities, embodiments are not limited thereto. For example, the photodiode 70 can include only the first impurity region 71 and the third impurity region 73.

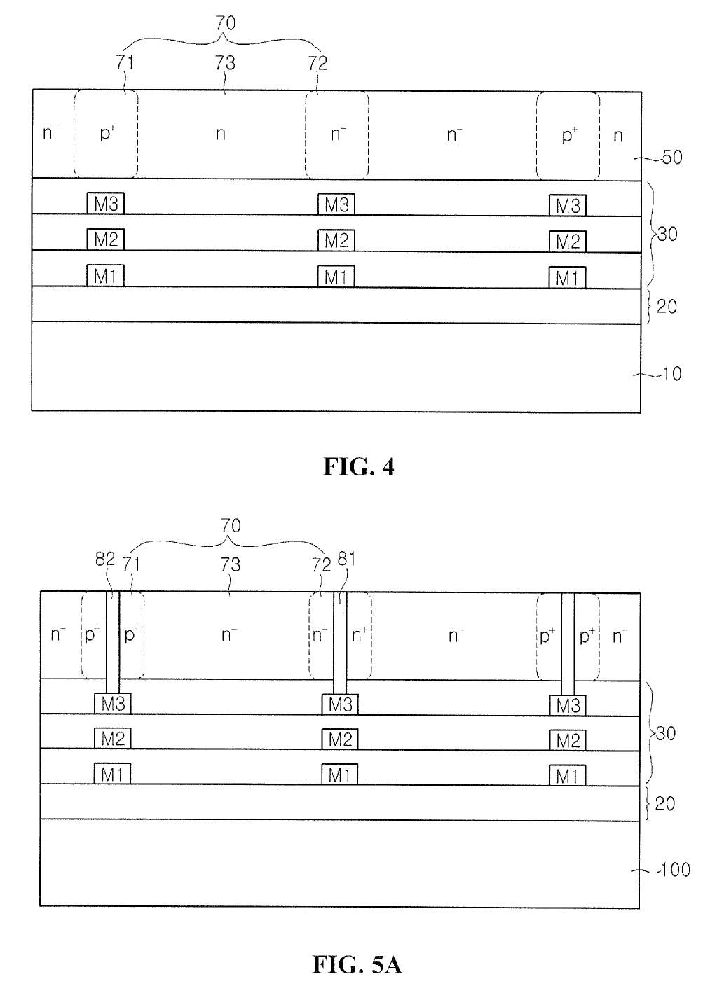

Thereafter, the second photoresist pattern 62 can be removed, and the second substrate 50 including the photodiode 70 can be bonded to the first substrate 100, as shown in FIG. 4.

As a result, the photodiode 70 can be provided on the metal line layer 30.

Although the photodiode 70 is described as being formed in the entire region of the second substrate 50, the photodiode 70 can be locally formed in a portion of the second substrate 50. Then, for the case where the photodiode 70 is locally formed in the portion of the second substrate 50, the remaining portions of the second substrate 50 other than the photodiode 70 can be removed.

Next, as shown in FIG. 5A, a first contact 81 and a second contact 82, which penetrate the photodiode 70 and contact the third metal (M3), can be formed.

FIG. 5A is a cross-sectional view of the first substrate 100 including the circuitry layer 20, the metal line layer 30 and the photodiode 70, and FIG. 5B is a detailed view according to one embodiment of the first substrate 100 on which the circuitry layer 20 and the metal line 150a of the metal line layer 30 are formed.

The first and second contacts 81 and 82 can be formed by performing an etch process to form a via hole penetrating the photodiode 70. Then, the via hole can be filled with metal, such as tungsten (W), titanium nitride (TiN), or aluminum (Al).

The first contact 81 can be formed to penetrate the first impurity region 71 and the second contact 82 can be formed to penetrate the second impurity region 72.

When the first contact 81 and the second contact 82 are formed, the second contact 82 can penetrate some of the metal line layer 30 in order to contact the third metal M3 (153).

The photodiode 70 is positioned between the first contact 81 and the second contact 82, and can be symmetrically arranged about the First contact 81 or second contact 82 with respect to an adjacent photodiode.

The first contact 82 can be used to transmit a signal generated in the photodiode 70 to a circuitry region from the second impurity region 72 through the metal line 150.

Thereafter, although not shown in the drawings, an electrode, a color filter array and a microlens can be formed on the photodiode 70. In one embodiment, the second contact 82 can connect to the electrode and/or can connect to a peripheral circuit region (not shown).

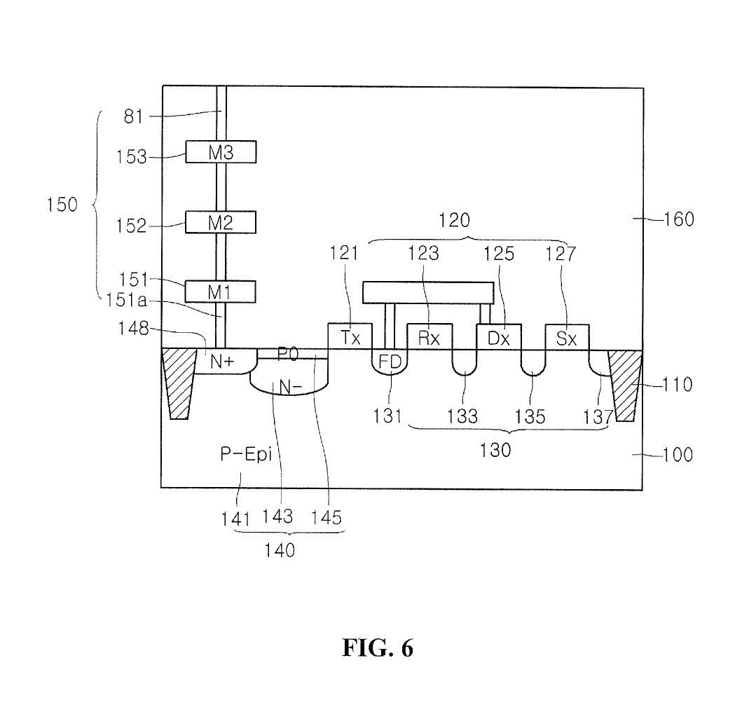

FIG. 6 is a cross-sectional view of an image sensor according to another embodiment, and is a detailed view of a first substrate on which a metal line 150 is formed.

The present embodiment can employ the technical characteristics of the embodiments described with respect to FIGS. 1 to 5.

For example, according to the present embodiment, a device can be designed such that a potential difference is generated between the source and drain of the transfer transistor Tx to fully dump photo charges.

Also, according to an embodiment, a charge connecting region can be formed between the photodiode and the readout circuitry to facilitate passage of the photo charge, thereby minimizing a dark current source and inhibiting the saturation and sensitivity from being reduced.

Meanwhile, unlike the embodiments described with respect to FIG. 5B, the present embodiment exemplarily shows that a first conductive type connection region 148 can be formed at one side of the electrical junction region 140.

According to embodiments, an N+ connection region 148 for an ohmic contact can be formed in the P0/N−/P− junction 140. At this time, the N+ connection region 148 and an M1C contact 151a may act as a leakage source. This is because in operation, a reverse bias is applied to the P0/N−/P− junction 140 and an electric field EF is generated in a surface of the Si substrate. Under the generated electric field, a crystal defect generated in forming the contact acts as a leakage source.

Also, in the case where the N+ connection region 148 is formed on a surface of the P0/N−/P− junction 140, an additional electric field is generated by the N+/P0 junction 148/145, which may also act as a leakage source.

Accordingly, the present embodiment provides a layout in which a doping into the P0 layer is not performed. Instead, a first contact plug 151a is formed on an active region including the N+ connection region 148, and the first contact plug 151a is connected to the N− junction 143 through the N+ connection region 148.

According to the present embodiment, an electric field is not generated in a surface of the silicon substrate, which can contribute to a decrease in the dark current of the 3-D integrated CIS.

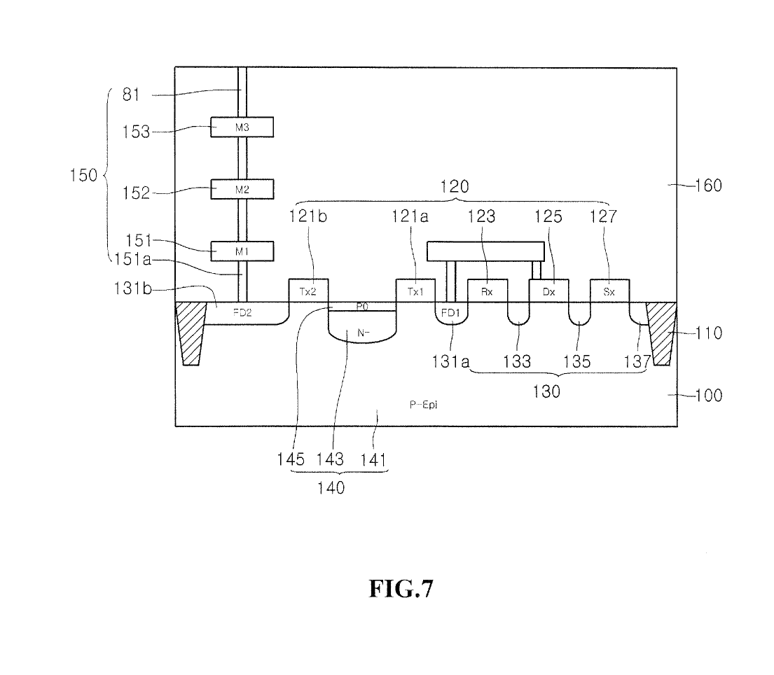

FIG. 7 is a cross-sectional view of an image sensor according to a yet another embodiment, and is a detailed view of a first substrate on which a metal line 150 is formed.

The present embodiment can employ the technical characteristics of the embodiments described with reference to FIGS. 1 to 5.

For example, according to the present embodiment, a device can be designed such that a potential difference is generated between the source and drain of the transfer transistor Tx to fully dump photo charges.

Also, according to an embodiment, a charge connecting region can be formed between the photodiode and the readout circuitry to facilitate passage of the photo charge, thereby minimizing a dark current source and inhibiting the saturation and sensitivity from being reduced.

The readout circuitry 120 on the first substrate 100 according to one embodiment will be described in more detail with reference to FIG. 7.

In particular, a first transistor 121a and a second transistor 121b can be formed on the first substrate 100. For example, the first transistor 121a and the second transistor 121b can be a first transfer transistor and a second transfer transistor, respectively, but embodiments are not limited thereto. The first transistor 121a and the second transistor 121b can be formed concurrently or sequentially.

Thereafter, an electrical junction region 140 can be formed between the first transistor 121a and the second transistor 121b. In one embodiment, the electrical junction region 140 can be a PN junction 140, but embodiments are not limited thereto.

For example, the PN junction 140 according to an embodiment can include a first conductive type ion implantation layer 143 on a second conductive type epi layer (or well) 141, and a second conductive type ion implantation layer 145 on the first conductive type ion implantation layer 143.

In a specific embodiment, the PN junction 140 can be a P0(145)/N−(143)/P−(141) junction.

A first conductive type high concentration connection region 131b connected with the metal line 150 can be formed at one side of the second transistor 121b. The first conductive type high concentration connection region 131b is a high concentration N+ junction and can act as a floating diffusion region (FD2) 131b.

In this embodiment, the readout circuitry can perform a 4Tr operation by moving electrons generated in the photodiode to the N+ junction 131b of the silicon substrate 100 and again moving the electrons of the N+ junction 131b to the N− junction 143.

In this embodiment, the P0/N−/P− junction 140 and the N+ junction 131b are formed separately from each other, as shown in FIG. 7.

By separating the N+ junction 131b and the PNP junction 140, dark current can be inhibited from being generated.

Accordingly, a contact can be formed in the N+/P-Epi junction 131b.

In a signal readout, a gate of the second transistor (Tx2) 121b is turned on and a gate of the first transistor (Tx1) 121a is turned on, such that the electrons generated in the photodiode 70 on a chip transfer to the P0/N−/P− junction 140 and move to the first floating diffusion region (FD1) 131a, thereby allowing correlated double sampling (CDS).

As described above, the method for manufacturing an image sensor according to an embodiment can improve the dark characteristic and enhance the sensitivity of the image sensor by bonding a second crystalline substrate on which a photodiode is formed to a first substrate on which a circuitry including a lower metal line is formed.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing an image sensor, comprising:
preparing a first substrate on which a metal line and a readout circuitry are formed;
providing a photodiode comprising a first impurity region and a second impurity region on the first substrate; and
forming a first contact and a second contact penetrating the photodiode, wherein the first contact penetrates the first impurity region of the photodiode, wherein the second contact penetrates the second impurity region of the photodiode to contact the metal line.

2. The method according to claim 1, wherein providing the photodiode comprises:
forming the photodiode in a second substrate; and
bonding the photodiode on the first substrate.

3. The method according to claim 2, wherein the photodiode further comprises a third impurity region between the first impurity and the second impurity regions, wherein forming the photodiode comprises:
providing a lightly doped n-type crystalline substrate, wherein the second substrate comprises the lightly doped n-type crystalline substrate;
implanting p-type impurities into the lightly-doped n-type crystalline substrate to form the first impurity region; and
implanting n-type impurities into the lightly doped n-type crystalline substrate at a region spaced apart from a side of the first impurity region,
wherein the lightly doped n-type crystalline substrate between the first impurity region and the second impurity region provides the third impurity region.

4. The method according to claim 2, wherein the photodiode further comprises a third impurity region between the first impurity and the second impurity regions, wherein forming the photodiode comprises:
providing a p-type doped crystalline substrate, wherein the second substrate comprises the p-type doped crystalline substrate;
implanting a n-type impurities into the p-type doped crystalline substrate to form the third impurity region; and
implanting n-type impurities into the p-type closed crystalline substrate to form the second impurity region having a higher concentration than the third impurity region,
wherein remaining regions of the p-type doped crystalline substrate provide the first impurity region.

5. The method according to claim 1, wherein the photodiode further comprises a third impurity region between the first impurity region and the second impurity region.

6. The method according to claim 5, wherein the first impurity region, the third impurity region, and the second impurity region of the photodiode are provided symmetrically about a longitudinal axis of the first contact.

7. The method according to claim 1, wherein the preparing of the first substrate comprises:
forming the readout circuitry on the first substrate;
forming an electrical junction region in the first substrate such that the electrical junction region is electrically connected with the readout circuitry; and
forming the metal line on the first substrate such that the metal line is electrically connected with the electrical junction region.

8. The method according to claim 7, wherein the forming of the electrical junction region comprises:
forming a first conductive type ion implantation region in the first substrate; and
forming a second conductive type ion implantation region on the first conductive type ion implantation region.

9. The method according to claim 7, further comprising forming a first conductive type connection region in the first substrate between the electrical junction region and the metal line, wherein the first conductive type connection region is electrically connected with the metal line.

10. The method according to claim 7, wherein the electrical junction region has an ion implantation concentration lower than a floating diffusion region of the readout circuitry.

11. The method according to claim 7, wherein the readout circuitry of the first substrate comprises a first transistor and a second transistor formed to be connected in series on the first substrate, and wherein the electrical junction region is formed between the first transistor and the second transistor.

12. An image sensor comprising:
a semiconductor substrate having a metal line and a readout circuitry formed thereon;
a photodiode on the semiconductor substrate, the photodiode comprising a first impurity region and a second impurity region in a crystalline region; and
a first contact and a second contact penetrating the photodiode, wherein the first contact penetrates the first impurity region of the photodiode, wherein the second contact penetrates the second impurity region of the photodiode to connect to the metal line.

13. The image sensor according to claim 12, further comprising an oxide layer between the semiconductor substrate on which the metal line and the readout circuitry are formed and the photodiode.

14. The image sensor according to claim 12, wherein the first impurity region comprises p-type impurities and the second impurity region comprises n-type impurities.

15. The image sensor according to claim 12, wherein the photodiode further comprises a third impurity region between the first impurity region and the second impurity region.

16. The image sensor according to claim 15, wherein the first impurity region comprises p-type impurities, wherein the second impurity region comprises n-type impurities at a high concentration, and wherein the third impurity region comprises n-type impurities at a low concentration.

17. The image sensor according to claim 12, wherein the readout circuitry comprises an electrical junction region formed in the first substrate, wherein the electrical junction region comprises:
a first conductive type ion implantation region formed in the first substrate; and
a second conductive type ion implantation region on the first conductive type ion implantation region.

18. The image sensor according to claim 17, further comprising a first conductive type connection region between the electrical junction region and the metal line, wherein the first conductive type connection region is electrically connected with the metal line.

19. The image sensor according to claim 12, wherein the readout circuitry has a potential difference provided between a source and a drain of a transistor.

20. The image sensor according to claim 19, wherein the transistor is a transfer transistor, and the source of the transistor has an ion implantation concentration lower than a floating diffusion region at the drain of the transistor.
